(19) United States
(12) Patent Application Publication
(10) Pub. No.: US 2024/0101412 A1
(43) Pub. Date: Mar. 28, 2024

(54) Support Device for One or More MEMS Components

(71) Applicants: Robert Bosch GmbH, Stuttgart (DE); Carl Zeiss SMT GmbH, Oberkochen (DE)

(72) Inventors: Joachim Friedl, Reutlingen (DE); Jan Stiedl, Pliezhausen (DE)

(21) Appl. No.: 18/460,760

(22) Filed: Sep. 5, 2023

(30) Foreign Application Priority Data
Sep. 28, 2022 (DE) 102022210285.1

(51) Int. Cl. B81B 3/00; B81C 1/00

(52) U.S. Cl. CPC B81B 3/0072; B81C 1/00666; B81B 2201/042; B81B 2207/012; B81B 2207/07; B81C 2203/033; G02B 26/0833

(57) ABSTRACT

The invention relates to a device (100) for supporting one or more MEMS components (160), comprising a base component (110), which substantially consists of a first material with a first coefficient of expansion α₁, an interposer (120), which is integrally bonded to the base component (110) in one or more first connection regions (140) and substantially consists of a second material with a second coefficient of expansion α₂, and a support substrate (130), which is integrally bonded to the interposer (120) in one or more second connection regions (150) and substantially consists of a third material with a third coefficient of expansion α₃, wherein the support substrate (130) is configured to support the one or more MEMS components (160), and for the coefficients of expansion the following holds true: α₁>α₂≥α₃, preferably α₁>α₂=α₃. The invention also relates to a system (105) comprising a device (100) according to the invention and the one or more MEMS components (160), and to a method for producing a device (100) according to the invention.

The present invention concerns the field of MEMS components and relates to a device for supporting one or more MEMS components, to a system comprising such a device and one or more MEMS components, and to a method for producing a device according to the invention.

### PRIOR ART

Devices comprising micro-electromechanical systems (MEMS) and corresponding MEMS-based components (MEMS components), such as sensors, micro-mirror arrays or micro-mirror actuators, are used nowadays in a multiplicity of devices, for example in measuring apparatuses, smartphones, projectors, head-up displays, barcode readers, mask exposure units in semiconductor manufacture, and microscopes. Thus, micro-mirror arrays are known, for example from the documents DE 10 2013 208 446 A1, EP 0 877 272 A1 and WO 2010/049076 A2.

### DISCLOSURE OF THE INVENTION

The invention proposes a device for supporting one or more MEMS components and a system comprising such a device and one or more MEMS components. A method for producing a device according to the invention is also disclosed.

A first aspect of the invention proposes a device for supporting one or more MEMS components, preferably a micro-mirror array. This device comprises a base component, which substantially consists of a first material with a first coefficient of thermal expansion α₁, an interposer, which is integrally bonded to the base component in one or more first connection regions and substantially consists of a second material with a second coefficient of thermal expansion α₂, and a support substrate, which is integrally bonded to the interposer in one or more second connection regions and substantially consists of a third material with a third coefficient of thermal expansion α₃. In this case, the support substrate is configured to support the one or more MEMS components, and for the coefficients of thermal expansion the following holds true: α₁>α₂≥α₃ and preferably α₁>α₂=α₃. The support substrate may for example have a cuboidal or cylindrical outer shape.

Within the meaning of the present invention, an interposer is understood to mean a coupling element for mechanical coupling between two components that may, but does not have to, comprise electrical connections and electric components. The coefficient of thermal expansion, also referred to as heat expansion coefficient, is also referred to below in short as coefficient of expansion. The first coefficient of expansion α₁ may be a coefficient of linear thermal expansion, a coefficient of areal thermal expansion, or a coefficient of volumetric thermal expansion. The same applies to the second coefficient of expansion α₂ and the third coefficient of expansion α₃. To compare the coefficients of expansion of the three materials, the same type of coefficient of expansion must be selected. Accordingly, the coefficients of expansion that are to be compared by means of the inequation α₁>α₂≥α₃ are always the same type of coefficient of expansion, indicated by the identical symbol α.

There are consequently one or more integrally bonded connections both between the base component and the interposer and between the interposer and the support substrate. In this respect, these integrally bonded connections extend over a first and a second connection region, respectively. Here, a connection region in relation to two components denotes a region on both sides of an integrally bonded connection between the two components in which the integrally bonded connection is formed, that is to say exists between two surfaces of the components. A connection region may thus always be assigned two components and its shape defines an associated geometric basic area.

According to the invention, it has been found that there is a need to couple MEMS components, when used in a device, to an element of a superordinate assembly in such a way that a mechanically stable and low-distortion connection exists, even at fluctuating temperatures. Typically, MEMS components are disposed on a support substrate having a coefficient of expansion that frequently differs from the coefficient of expansion of a component of a superordinate structure to which the MEMS component is coupled by means of the support substrate. This component, which serves for connection to the superordinate assembly, is referred to as base component within the context of this invention. Therefore, it may be the case that the base component consists of a metal, for example copper, while the support substrate consists for example of a ceramic. As a result, in the event of changes in temperature, thermal stresses, which can also be referred to as thermally induced mechanical stresses, arise between the base component and the support substrate. The quality of many devices comprising one or more MEMS components is adversely affected by thermal stresses. As a result, for example, in the case of devices comprising micro-mirror arrays, thermal stresses between the components used can lead to distortion and in particular deformations and thus impaired co-planarity of the individual mirror elements.

Changes in temperature, which cause thermal stresses, may for example arise in the course of the manufacture of such a device, but also during operation of the device. It is also possible for thermal stresses to be a consequence of the manufacture of the device taking place at a different temperature than its operation. Thermal stresses may in particular weaken integrally bonded connections between the support substrate and the base component, since they are often not very ductile and, owing to their low elastic deformability, are not suitable for withstanding the thermal stresses resulting from changes in temperature. This is especially disadvantageous when there is only limited space on the support substrate that can be utilized for integrally bonded connections owing to the MEMS component and/or components, for example electronic components, that are connected thereto. Integrally bonded connections thus often cannot be designed in a way that would actually be necessary for a stable connection, for example over a sufficiently large and/or otherwise geometrically advantageous area of a connection region. On the other hand, however, integrally bonded connections are necessary for a multiplicity of applications in order to achieve the hermetic sealing of components.

According to the invention, this problem of mechanically stable coupling between the support substrate and the base component in the event of use of integrally bonded connections is resolved by the use of an interposer between the base component and the support substrate. In this case, the material of the interposer is selected such that it has a lower coefficient of expansion than the material of the base component and at the same time has a larger or preferably the same coefficient of expansion as the support substrate. The result of this selection of material is that the thermal stresses acting on the integrally bonded connections with the support substrate are reduced. This makes it possible to geometrically more advantageously design and place the integrally bonded connections between the interposer and the support substrate, since they are exposed to thermal stresses to a lower degree. In particular in the case of an identical coefficient of expansion of the interposer and the support substrate, thermal stresses between these two components can be avoided. Instead, although corresponding thermal stresses continue to arise at the connections between the base component and the interposer, since the interposer can have a freer form on the base component side, the interposer can be designed such that here, in spite of the thermal stresses, a sufficiently stable integrally bonded connection is produced. By contrast to an integrally bonded connection between the support substrate and the base component, it is therefore not necessary to take into account the structure of the one or more MEMS components and/or further components on the support substrate that are to be supported, such as electronic components, when coupling is done via an interposer. Preferably, in the case of a device according to the invention, the base component and the support substrate are disposed on opposite sides of the interposer, in order to have the greatest possible freedom in the configuration of the integrally bonded connections both between the base component and the interposer and between the interposer and the support substrate.

The method used to integrally join the base component, the interposer and the substrate support may be for example soldering, sintering and/or welding. Depending on the method selected, it is possible for a device according to the invention to also comprise a first connection layer between the base component and the interposer and a second connection layer between the interposer and the support substrate, by way of which the respective integrally bonded connection is obtained, for example a soldered layer or a sintered layer, such as a silver sintered layer.

In a preferred configuration of the device according to the invention, the base component and the support substrate are in mechanical contact and thus also in thermal contact with one another exclusively via the interposer. There are therefore no other elements connecting the two components that, without the interposer, produce mechanical contact between the base component and the interposer. This makes it possible to ensure that the support substrate is optimally mechanically connected to the base component and thermal stresses cannot arise in other ways.

It is particularly advantageous when the interposer has a polygonal, in particular rectangular, or an oval, in particular circular, basic area, wherein the basic area comprises the first and/or the second connection region. Such a shape of a basic area makes it possible to ensure particularly good mechanical stability and an optimum integrally bonded connection with the base component and/or the support substrate.

Preferably, in the case of a device according to the invention, the second material, that is to say that of the interposer, and the third material, that is to say that of the support substrate, are identical. This has the advantage that an identical coefficient of expansion is ensured. The first material is preferably a metal, for example copper, or contains a metal. In particular, metal alloys, for example a steel, are conceivable. The second material for the interposer and/or the third material for the support substrate is preferably a ceramic, for example an Al₂O₃ ceramic (aluminium oxide ceramic) or an AlN ceramic (aluminium nitride ceramic), or the second material and/or the third material contain(s) such a ceramic.

In a particularly preferred configuration of the device according to the invention, the base component and the interposer are connected to one another exclusively in the one or more first connection regions and the interposer and the support substrate are connected to one another exclusively in the one or more second connection regions. There are thus no integrally bonded connections or non-integrally bonded connections between the corresponding components outside these regions. Preferably, there is exactly one first connection region. This is advantageous, since it makes it possible to achieve a particularly simple and mechanically stable connection between the interposer and the base component. The design freedom on the base component side as regards the shape of the interposer makes it possible to place this first connection region flexibly and advantageously. It is therefore in particular conceivable to position the first connection region centrally on a basic area of the interposer. This makes it possible to achieve a particularly stable mechanical connection.

For the configuration of the geometry of the integrally bonded connections, that is to say the connection regions, there are multiple particularly preferred and not mutually exclusive variants which enable particularly high mechanical stability of the device according to the invention and its connections and/or utilize the flexibility in terms of the selection of the geometry of the interposer. For the following description of these variants, it is assumed that there is no integrally bonded connection between the base component and the interposer or between the interposer and the support substrate that is not present in one of the connection regions, that is to say in one of the one or more first connection regions or in one of the one or more second connection regions. Options are shown, in particular for designing an integrally bonded connection between the interposer and the base component that is stable with respect to thermal stresses.

In a first variant, the first or the multiple first connection regions together cover a first area of the interposer and the second or the multiple second connection regions together cover a second area of the interposer, wherein the first area is larger (with respect to the surface area) and/or otherwise geometrically more advantageous than the second area. In this respect, the multiple first and/or second connection regions, in the case of the surface areas, may correspondingly be multiple disjoint sub-areas. In a second variant, each of the one or more first connection regions has a different basic area, that is to say different in terms of the size and/or shape, than each of the one or more second connection regions. In a third variant, the plurality, preferably each of the one or more first connection regions, has a larger and/or otherwise geometrically more advantageous basic area than any of the one or more second connection regions. In a fourth variant, each of the one or more first connection regions has an oval, in particular an elliptical or circular basic area, and/or each of the one or more second connection regions has a rectangular basic area. In particular, the one or more first connection regions may have an annular form.

Within the meaning of the invention, a first area is considered to be otherwise geometrically more advantageous than a second area when a) the maximum lateral extent of the area in relation to the surface area of the area is smaller for the first area than for the second area and/or b) the polar area moment of inertia is smaller with regard to the geometric centroid of the first area than that of the second area and/or c) the perimeter of the first area in comparison with the second area has no corners (either inner or outer corners) or has few corners. The latter is particularly advantageous since this avoids a notch effect to the best possible extent. In the case of the first two alternatives, strongly pronounced thermal stresses owing to excessive lateral expansions are avoided. The above definition applies accordingly for the case of a first and a second basic area of connection regions. If an area which consists of multiple disjoint sub-areas is considered, a first area is to be considered as otherwise geometrically more advantageous than a second area when at least one of the sub-areas of the first area is otherwise geometrically more advantageous than each of the sub-areas of the second area.

A second aspect of the invention proposes a system which comprises a device according to the invention for supporting one or more MEMS components and comprises the one or more MEMS components. The one or more MEMS components may for example be a micro-mirror or a micro-mirror array. In this case, the one or more MEMS components are disposed on a first side of the support substrate. Here, this side is preferably opposite a second surface of the support substrate that comprises the one or more second connection regions.

Particularly preferably, an electronic component is disposed on a second side of the support substrate that is different from the first side, wherein the second side comprises the one or more second connection regions and there is an electrical connection between the electronic component and the one or more MEMS components. The electronic component may for example serve to control the one or more MEMS components. For example, the electronic component may be an ASIC (application-specific integrated circuit). The support substrate may also be in the form of a rewiring element. Preferably, the interposer also has a cutout which at least partially laterally encloses the electronic component, preferably on multiple sides, in order to protect it against external influences. For example, the interposer may comprise one or more side walls which may be suitable, for example, for protecting the electronic component against external influences, such as external particles.

A third aspect of the invention proposes a method for producing a device for supporting one or more MEMS components. Preferably, this is a device according to the invention as described above. First of all, in the course of the method, a base component, which substantially consists of a first material with a first coefficient of thermal expansion α₁ is provided, as are an interposer, which substantially consists of a second material with a second coefficient of thermal expansion α₂, and a support substrate, which substantially consists of a third material with a third coefficient of thermal expansion α₃, wherein the support substrate is designed to support the one or more MEMS components.

Preferably, for the coefficients of expansion it holds true here that α₁>α₂≥α₃, preferably α₁>α₂=α₃. An integral bonding process, for example soldering, sintering and/or welding, is used to connect the interposer to the base component and to the support substrate in such a way that the base component and the support substrate are in contact exclusively via the interposer after the integral bonding operation. In this respect, the interposer can be connected to the base component temporally before the interposer is connected to the support substrate, but the reverse order is conceivable. In particular, the interposer may be connected to the support substrate before the interposer is connected to the base component, in order to protect the support substrate, and thus possibly already connected components, for example a MEMS component and/or an electronic component, by way of the interposer, for example against undesired mechanical damage in the course of the manufacture of the device.

It may also be advantageous when the one or more MEMS components is already on the support substrate before the support substrate is connected to the interposer. The one or more MEMS components are thus preferably connected to the support substrate in advance, before the support substrate is connected to the interposer. The one or more MEMS components may for example be connected to the MEMS support substrate in advance by means of an integral bonding process, for example by means of soldering and/or sintering and/or adhesive bonding. This also applies to a possible electronic component, for example for controlling the one or more MEMS components, which likewise may be connected to the support substrate before the support substrate is connected to the interposer. As an alternative, the one or more MEMS components and/or the electronic component may, however, likewise be connected to the support substrate only after the interposer has been connected to the support substrate.

### Advantages of the Invention

The present invention shows options for mechanically stably coupling one or more MEMS components on a support substrate to a superordinate assembly by means of integrally bonded connections. In particular, in this respect thermal stresses resulting from material pairs having different coefficients of expansion are avoided and/or displaced to non-critical connections of the device.

Typically, in the case of the integrally bonded connection to a support substrate, there is great restriction in terms of possible designs. This is caused in particular by the components that are on the support substrate, since corresponding installation space is kept free for them and cannot be used for the connections. Frequently, such structural restrictions mean that mechanically unfavourable connection regions are required, for example because they have especially narrow designs. In the case of rectangular connection regions, it is also possible for notch effects and corresponding increased stresses in the connections to arise, the stresses being particularly critical in the case of correspondingly thin connection regions. The connection regions are frequently also laterally expanded to a great extent, as a result of which especially strongly pronounced thermal stresses can arise. The intention is frequently also to use integrally bonded connections to obtain a hermetically sealed segmentation of a device in the case of the use of MEMS components. This renders necessary an integrally bonded connection by means of materials which typically have low ductility and therefore are particularly susceptible to thermal stresses.

The approach according to the invention via an interposer makes it possible to increase the mechanical stability of the integrally bonded connections with the support substrate and in particular counteract thermal stresses. To that end, an interposer of a material having an identical or at least similar coefficient of expansion as that of the support substrate is inserted between the basic component, which serves for coupling to the superordinate assembly, and the support substrate.

The structural flexibility in terms of the design of the interposer also enables a variety of options in terms of the form of the one or more connection regions between the interposer and the base component: The one or more connection regions with the base component can be designed freely and in optimized fashion since, owing to their arrangement in a different plane, the corresponding connections no longer compete with the components mounted on the support substrate. If a single first connection region is used, it may also advantageously be disposed in the middle of the base area to be connected of the interposer and in particular have a circular or annular form, in order to avoid a notch effect. The lateral extent of the one or more first connection regions may also be optimized such that both sufficient mechanical coupling between the interposer and the base component is ensured and thermal stresses owing to the lateral extent are limited. The mechanical coupling between the support substrate and the base component thus becomes considerably more stable as a result of the thermal stresses being displaced to the fundamentally non-critical connections between the interposer and the base component.

The use of an interposer according to the present invention furthermore also makes it possible to counteract a thermally induced distortion that could have an adverse effect on the one or more MEMS components of a device. This increases the quality of the device. In particular in the case of a micro-mirror array as MEMS component of a system according to the invention, this ensures the best possible coplanarity of the mirror elements of the micro-mirror array even in the event of fluctuating temperatures.

### BRIEF DESCRIPTION OF THE DRAWINGS

Embodiments of the invention are explained in more detail with reference to the drawings and the following description.

In the figures:

FIG. 1A shows a schematic illustration of an exemplary device according to the invention and an exemplary system according to the invention, in a side view;

FIG. 1B shows a schematic illustration of the connecting layers and the connection regions of the exemplary device according to the invention, in a plan view; and

FIG. 2 schematically shows a flow diagram of an exemplary method according to the invention for producing an exemplary device according to the invention.

### EMBODIMENTS OF THE INVENTION

In the following description of the embodiments of the invention, identical or similar elements are designated with the same reference signs, a repeated description of these elements in individual cases being omitted. The figures illustrate the subject matter of the invention only schematically.

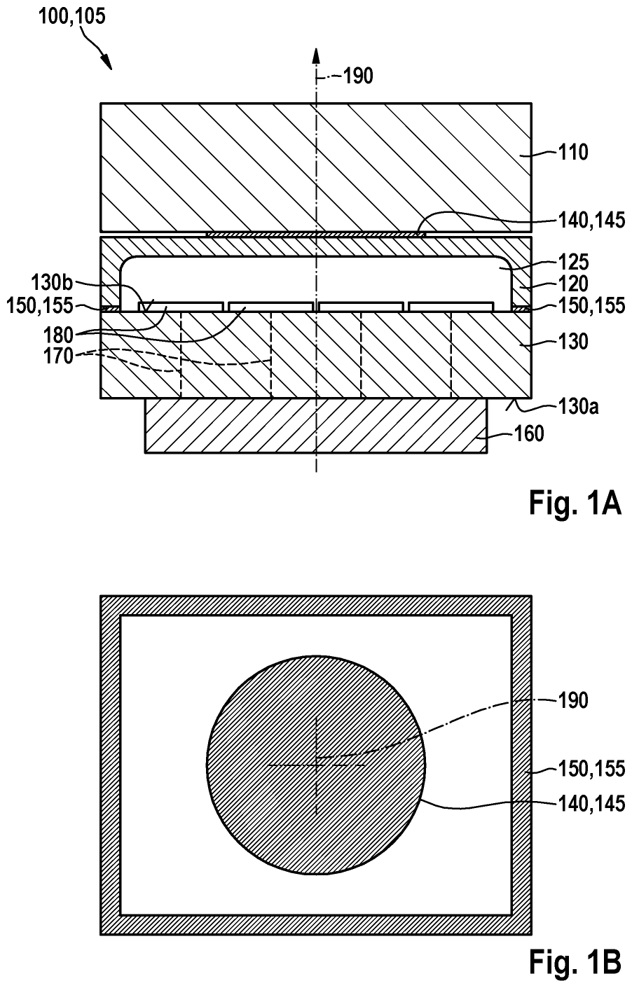

FIG. 1A shows a schematic illustration of an exemplary device 100 according to the invention and an exemplary system 105 according to the invention, in a side view.

More precisely, FIG. 1A shows a device 100 according to the invention for supporting a MEMS component 160 and at the same time the system 105, consisting of the device 100 according to the invention and the mounted MEMS component 160. This device 100 comprises a base component 110, which can be used for coupling to a superordinate assembly, an interposer 120, and a support substrate 130 with the MEMS component 160, for example a micro-mirror array, mounted on a first side 130a of the support substrate 130. Here, the base component 110 and the interposer 120 are integrally bonded to one another, with this integrally bonded connection being realized in a first connection region 140. There is also an integrally bonded connection between the interposer 120 and the support substrate 130 in a second connection region 150. In this case, the interposer 120 and the support substrate 130 consist substantially of the same first material, for example a ceramic, but the base component 110 consists of a second material, for example a metal, such as copper, having a coefficient of expansion which differs from the coefficient of expansion of the first material.

There are also electronic components 180 on the support substrate 130, specifically on the second side 130b of the support substrate 130 that is opposite the first side 130a. They are disposed in a cutout 125 of the interposer 120 and connected to the MEMS component 160 via electrical connections 170, which extend through the support substrate 130. The electronic components 180 may for example be ASICs, which serve to actuate the MEMS component 160. Also depicted are a first connecting layer 145 and a second connecting layer 155, which are part of the integrally bonded connections, in the area of the connection regions 140, 150. The layers may for example be soldered and/or sintered layers.

In this respect, the elements 110, 120, 130, 140, 145, 150, 155 and 160 are disposed centrally in relation to one another. This is illustrated in the drawing by the depicted axis 190 which extends through the middle. In this respect, the axis 190 extends perpendicularly to surfaces of the individual elements 110, 120, 130, 140, 145, 150, 155, 160, that is to say also perpendicularly to the sides 130a, 130b of the support substrate.

FIG. 1B illustrates the connecting layers 155, 145 and the connection regions 140, 150 from FIG. 1A in a plan view. As can be seen, they have different shapes: The first connection region 140 and correspondingly the first connecting layer 145 have circular forms, while the second connection region 150 and the second connecting layer 155 have the form of a square, narrow frame, which was forced through the cutout 125 required by the electronic components 180. Instead of a circular connection region 140 and a circular connecting layer 145, an annular shape is also conceivable. Such an annular shape may for example be advantageous if a cylindrical cutout is disposed in the interposer 120 centrally about the axis 190, for example for the purpose of feeding electric lines. This cutout might be hermetically sealingly enclosed by an annular connecting layer 145. The integrally bonded connection, illustrated in FIG. 1B, of the second connection region 150 is mechanically in principle considerably less stable than the integrally bonded connection of the first connection region 140: Owing to the greater lateral extent, potential thermal stresses act more strongly here than in the first connection region 140, and notch effects and increased stresses resulting from the corners are to be expected. They are completely avoided in the first connection region 140 owing to the circular shape, this not being possible for the second connection region 150 because of the structure. The selection of substantially identical materials for the support substrate 130 and the interposer 120 that is made then avoids thermal stresses at critical locations: As a result of the different coefficients of expansion, thermal stresses arise only between the base component 110 and the interposer 120, but these thermal stresses are not critical owing to the geometrically more advantageous integrally bonded connection.

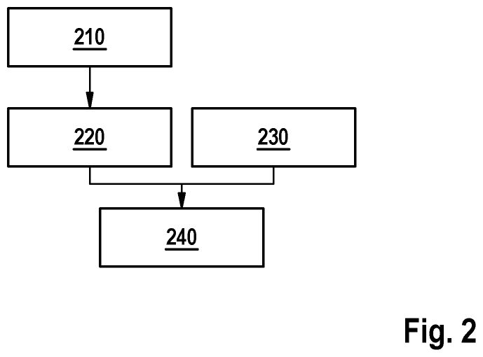

FIG. 2 schematically shows a flow diagram of an exemplary method according to the invention for producing an exemplary device 100 according to the invention. In the course of the method, in step 210, a base component 110, which substantially consists of a first material with a first coefficient of thermal expansion α₁, an interposer 120, which substantially consists of a second material with a second coefficient of thermal expansion α₂, and a support substrate 130, which substantially consists of a third material with a third coefficient of thermal expansion α₃, are provided, wherein the support substrate 130 is designed to support the one or more MEMS components 160. In step 220, the MEMS component 160 is mounted on and integrally bonded to the support substrate 130. This can be effected for example by soldering, sintering and/or adhesive bonding. Similarly, possible further components, such as electronic components 180, can be connected to the support substrate 130. The latter is done preferably after the MEMS component 160 has been mounted on the support substrate 130. In parallel, in step 230, the interposer 120 can be fastened to the base component 110 by means of an integral bonding process, for example by means of soldering, sintering and/or welding. In this respect, the base component 110 serves for connection to a superordinate assembly.

The support substrate 130 with the MEMS component 160 and the further components can lastly, in step 240, be connected to the interposer 120 also by an integral bonding process, such as soldering, sintering and/or welding. With a corresponding form of the interposer 120, it is possible to have the effect that sensitive components, such as the MEMS component 160 and the further components, on the support substrate 130 are protected by the interposer 120 for further steps of the manufacture and later on during operation of the device 100.

The invention is not limited to the exemplary embodiments described here and the aspects highlighted therein. On the contrary, a large number of modifications that are within the ability of a person skilled in the art are possible within the scope specified by the claims.

1. A device for supporting one or more MEMS components, comprising a base component, which substantially consists of a first material with a first coefficient of expansion α₁, an interposer, which is integrally bonded to the base component in one or more first connection regions and substantially consists of a second material with a second coefficient of expansion α₂, and a support substrate, which is integrally bonded to the interposer in one or more second connection regions and substantially consists of a third material with a third coefficient of expansion α₃, wherein the support substrate is configured to support the one or more MEMS components 46% and for the coefficients of expansion the following holds true: α₁>α₂≥α₃, preferably α₁>α₂=α₃.

2. The device according to claim 1, wherein the base component and the support substrate are on opposite sides of the interposer.

3. The device according to claim 1, comprising a first connecting layer between the base component and the interposer and a second connecting layer between the interposer and the support substrate.

4. The device according to claim 1, wherein the base component and the support substrate are in mechanical contact with one another exclusively via the interposer.

5. The device according to claim 1, wherein the interposer has a polygonal, in particular rectangular, or an oval, in particular circular, basic area, wherein the basic area comprises the first and/or the second connection region.

6. The device according to claim 1, wherein the second material and the third material are identical.

7. The device according to claim 1, wherein the first material is or contains a metal, preferably copper, and/or the second material is or contains a ceramic, and/or the third material is or contains a ceramic.

8. The device according to claim 1, wherein the base component and the interposer are connected to one another exclusively in the one or more first connection regions and the interposer and the support substrate are connected to one another exclusively in the one or more second connection regions.

9. The device according to claim 1, wherein the first connection region or multiple first connection regions together covers or cover a first area of the interposer and the second connection region or multiple second connection regions together covers or cover a second area of the interposer and the first area is larger and/or is otherwise geometrically more advantageous than the second area, and wherein there is no integrally bonded connection that is not present in one of the connection regions.

10. The device according to claim 1, wherein each of the one or more first connection regions has a different basic area than each of the one or more second connection regions, and wherein there is no integrally bonded connection that is not present in one of the connection regions.

11. The device according to claim 1, wherein the plurality, preferably each, of the one or more first connection regions has a larger and/or otherwise geometrically more advantageous basic area than each of the one or more second connection regions, and wherein there is no integrally bonded connection that is not present in one of the connection regions.

12. The device according to claim 1, wherein each of the one or more first connection regions has an oval basic area and/or each of the one or more second connection regions has a rectangular basic area, and wherein there is no integrally bonded connection that is not present in one of the connection regions.

13. A system comprising a device for supporting one or more MEMS components according to claim 1 and the one or more MEMS components, wherein the one or more MEMS components are disposed on a first side of the support substrate.

14. The system according to claim 13, wherein an electronic component is disposed on a second side of the support substrate that is different from the first side, wherein the second side comprises the one or more second connection regions and there is an electrical connection between the electronic component and the one or more MEMS components, wherein the interposer preferably has a cutout which at least partially laterally encloses the electronic component.

15. A method for producing a device for supporting one or more MEMS components comprising the following steps:
a. providing a base component, which substantially consists of a first material with a first coefficient of thermal expansion α₁, an interposer, which substantially consists of a second material with a second coefficient of thermal expansion α₂, and a support substrate, which substantially consists of a third material with a third coefficient of thermal expansion α₃, for supporting the one or more MEMS components; and
b. integrally bonding the interposer to the base component and to the support substrate in such a way that the base component and the support substrate are in contact exclusively via the interposer after the integral bonding operation.
